(19) United States
(12) Patent Application Publication
(10) Pub. No.: US 2018/0261620 A1
(43) Pub. Date: Sep. 13, 2018

(54) THREE DIMENSIONAL MEMORY DEVICE AND METHOD FOR FABRICATING THE SAME

(71) Applicant: MACRONIX INTERNATIONAL CO., LTD., Hsinchu (TW)

(72) Inventors: Guan-Ru Lee, Kaohsiung City (TW); Jia-Rong Chiou, Zhubei City (TW)

(21) Appl. No.: 15/454,103

(22) Filed: Mar. 9, 2017

(51) Int. Cl. H01L 27/11582; H01L 27/11568

(52) U.S. Cl. CPC H01L 27/11582; H01L 27/11568

(57) ABSTRACT

A 3D memory device includes a multi-layer stack, a first contact layer, a memory layer, a cannel layer. The multi-layer stack includes a plurality of conductive layers, a first opening and a second opening. The conductive layers are vertical stacked and insulated with each other. The first opening and the second opening respectively penetrate through at least two adjacent ones of the conductive layers. The first contact layer is disposed in the first opening and electrically connecting the conductive layers penetrated by the first opening. The memory layer is disposed in the second opening. The channel layer covers on the memory layer, wherein a plurality of memory cells are formed at cross points of the channel layer, the memory layer and the conductive layers penetrated by the second opening.

### BACKGROUND OF THE INVENTION

### Field of the Invention

The invention relates in general to a high density memory device and the method for fabricating the same, and more particularly to a three-dimensional (3D) memory device and the method for fabricating the same.

### Description of the Related Art

Non-volatile memory (NVM) which is able to continually store information even when the supply of electricity is removed from the device containing the NVM cell. A 3D memory devices, such as a 3D flash memory device having a single gate, a double gate or a surrounding gate, that includes a 3D memory cell array having vertical channels formed in a multi-layer stacks and possesses a higher density memory and excellent electrical characteristics, e.g. reliability in data storage and high operating speed has been widespreadly adopted by portable audiovisual entertainment devices, cell phones or digital cameras etc.

To take a single-gate vertical channel (SGVC) NAND memory device for example, the method for fabricating the SGVC NAND memory device includes steps as follows: A plurality of trenches are formed in a multi-layer stack, and a memory layer including a silicon oxide layer, a silicon nitride layer and another silicon oxide layer, and a poly-silicon channel layer are formed in sequence on the bottoms and sidewalls of the trenches, so as to define at least one U-shaped memory cell string structure having a plurality memory cells connected in series on the vertical sidewalls of the trenches.

Typically, the two memory cells that are disposed on the highest layer of the U-shaped memory cell string structure may respectively serve as the string selection (SSL) switch and the ground select line (GSL) switch, and the memory cells that are disposed on the bottom layers of the U-shaped memory cell string structure may serve as inversion assist gate (IG) switches used to control the other memory cells of the U-shaped memory cell string structure for performing program/erase processes. Because the SSL switch, the GSL switch and the IG switches may require threshold voltage higher than that of the other memory cells of the U-shaped memory cell string structure in order to avoid current leakage. To satisfy the threshold voltage requirements, a SSL switch, a GSL switch and a plurality of IG switches with thicker gate may be provided, to elongate the channel length thereof.

However, the process for forming the thicker gate of the SSL switch, the GSL switch and the IG switches may not integrated with the process for forming the gate of the other memory cells involved in the U-shaped memory cell string structure. Additional steps may be required and the manufacturing cost of the SGVC NAND memory device may be increased.

Therefore, there is a need of providing a 3D memory device and the method for fabricating the same to obviate the drawbacks encountered from the prior art.

### SUMMARY OF THE INVENTION

According to one embodiment of the present disclosure, a 3D memory device is provided, wherein the 3D memory device includes a multi-layer stack, a contact layer, a memory layer, a cannel layer. The multi-layer stack includes a plurality of conductive layers, a first opening and a second opening. The conductive layers are vertical stacked and insulated with each other. The first opening and the second opening respectively penetrate through at least two adjacent ones of the conductive layers. The contact layer is disposed in the first opening and electrically connecting the conductive layers penetrated by the first opening. The memory layer is disposed in the second opening. The channel layer covers on the memory is layer, wherein a plurality of memory cells are formed at cross points of the channel layer, the memory layer and the conductive layers penetrated by the second opening.

According to another embodiment of the present disclosure, method for fabricating a 3D memory device is provided, wherein the method includes steps as follows: Firstly, a multi-layer stack including a plurality of conductive layers, a first opening and a second opening is provided, wherein the conductive layers are vertical stacked arid insulated with each other; the first opening and the second opening respectively penetrate through at least two adjacent ones of the conductive layers. A contact layer is then formed in the first opening and electrically connecting the conductive layers penetrated by the first opening. Subsequently, a memory layer and a channel are formed in sequence in the second opening, whereby a plurality of memory cells are formed at cross points of the channel layer, the memory layer and the conductive layers penetrated by the second opening.

In accordance with the aforementioned embodiments of the present disclosure, a 3D memory device and the method for fabricating the same are provided, wherein the 3D memory device includes at least one vertical channel memory cell array having a plurality of transistor units formed in a multi-layer stack which includes a plurality of conductive layers vertical stacked and insulated with each other. At least one opening penetrating through at least two adjacent ones of the conductive layers is formed in the multi-layer stack prior to or after the forming of the vertical channel memory cell array. A contact layer is then formed in the opening to electrically connect the at least two adjacent ones of the conductive layers penetrated by the opening, so as to make the gate that are formed on the conductive layers penetrated by the opening have an equal potential.

In other words, the gates formed on the conductive layers electrically connected by the contact layer can be integrated to form an assembled switch having a greater threshold voltage and lower current leakage than the individual one of the other transistor units. When the assembled switch is applied in a vertical channel memory device, the process for forming the SSL switch, the GSL switch and the IG switches as well as the process forming the memory cells of the vertical channel memory device can be carried out simultaneously. The process for forming the vertical channel memory device can be simplified and the manufacturing cost can be reduced. In addition, because the conductive layers used to configure the assembled switch are electrically connected with each other, thus only one contact structure is need. Circuit wiring of the vertical channel memory device can be also simplified.

In some embodiments, since the gate of the SSL switch, the GSL switch and the IG switches are respectively formed by similar deposition process that is use to form the memory cells of the vertical channel NAND memory device, thus the gates thickness of the SSL switch, the GSL switch, the IG switches and the memory cells of the vertical channel NAND memory device may be substantially the same, and the etching deviation of a subsequent conductive layer etching-back process can be minimized. Such that, the down-stream process for forming the vertical channel NAND memory device can be performed on a robust basis, and the process window and yields thereof can be improved.

### BRIEF DESCRIPTION OF THE DRAWINGS

The above and other aspects of the invention will become better understood with regard to the following detailed description of the preferred but non-limiting embodiment(s). The following description is made with reference to the accompanying drawings.

FIGS. 1A to 1I are cross-sectional views illustrating a method for forming a 3D memory device in accordance with one embodiment of the present disclosure;

FIG. 2A is a perspective view illustrating the structure after a partial multi-layer stack is formed on a substrate;

FIG. 2B is a cross-sectional view taken along the section line S2 of FIG. 2A;

FIG. 3A is a prospective view illustrating the result after the process for patterning the partial multi-layer stack is performed on the structure depicted in FIG. 2A;

FIG. 3B is a cross-sectional view taken along the section line S3 of FIG. 3A;

FIG. 4A is a prospective view illustrating the result after a first contact layer is formed on the structure depicted in FIG. 3A;

FIG. 4B is a cross-sectional view taken along the section line S4 of FIG. 4A;

FIG. 5A is a prospective view illustrating the result after the dielectric material is deposited on the structure depicted in FIG. 4A;

FIG. 5B is a cross-sectional view taken along the section line S5 of FIG.

FIG. 6A is a prospective view illustrating the result after the multi-layer stack is formed on the structure depicted in FIG. 5A;

FIG. 6B is a cross-sectional view taken along the section line S6 of FIG. 6A;

FIG. 7A is a prospective view illustrating the result after the process for patterning the multi-layer stack is performed on the structure depicted in FIG. 6A;

FIG. 7B is a cross-sectional view taken along the section line S7 of FIG. 7A;

FIG. 8A is a prospective view illustrating the result after a contact layer is formed on the structure depicted in FIG. 6A;

FIG. 8B is a cross-sectional view taken along the section line S8 of FIG. 8A;

FIG. 9A is a prospective view illustrating the result after a dielectric material is deposited on the structure depicted in FIG. 8A;

FIG. 9B is a cross-sectional view taken along the section line S9 of FIG. 9A;

FIG. 10A is a prospective view illustrating the result after a plurality of trenches are formed on the structure depicted in FIG. 9A;

FIG. 10B is a cross-sectional view taken along the section line S10 of FIG. 10A;

FIG. 11A is a prospective view illustrating the result after a memory material layer and a channel layer are formed on the structure depicted in FIG. 13A;

FIG. 11B is a cross-sectional view taken along the section line S11 of FIG. 11A;

FIG. 12A is a prospective view illustrating the result after a plurality of SSL contact plugs, GSL contact plugs, and IG contact plug are formed on the structure depicted in FIG. 11A;

FIG. 12B is a cross-sectional view taken along the section line S12 of FIG. 12A; and

FIG.13 is a cross-sectional view illustrating the partial structure of a 3D memory device according to another embodiment of the present disclosure.

### DETAILED DESCRIPTION OF THE INVENTION

A 3D memory device and the method for fabricating the same is provided to simplify the manufacturing process, reduce the manufacturing cost and improve the process window and yields thereof. A number of embodiments of the present disclosure are disclosed below with reference to accompanying drawings.

However, the structure and content disclosed in the embodiments are for exemplary and explanatory purposes only, and the scope of protection of the present disclosure is not limited to the embodiments. Designations common to the accompanying drawings and embodiments are used to indicate identical or similar elements. It should be noted that the present disclosure does not illustrate all possible embodiments, and anyone skilled in the technology field of the invention will be able to make suitable modifications or changes based on the specification disclosed below to meet actual needs without breaching the spirit of the invention. The present disclosure is applicable to other implementations not disclosed in the specification. In addition, the drawings are simplified such that the content of the embodiments can be clearly described, and the shapes, sizes and scales of elements are schematically shown in the drawings for explanatory and exemplary purposes only, not for limiting the scope of protection of the present disclosure.

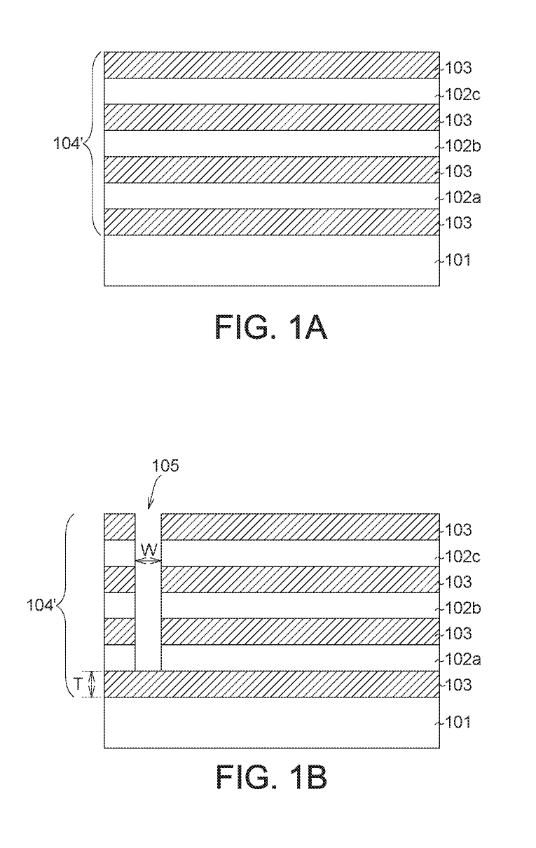

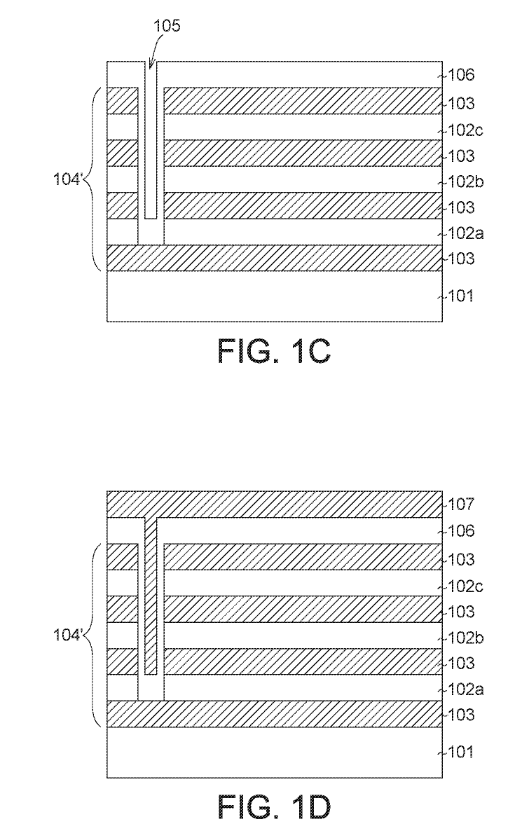

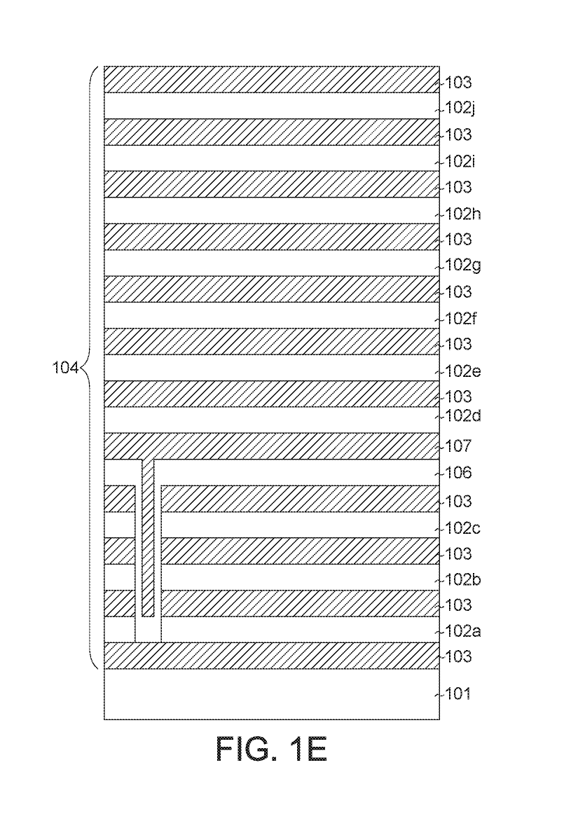

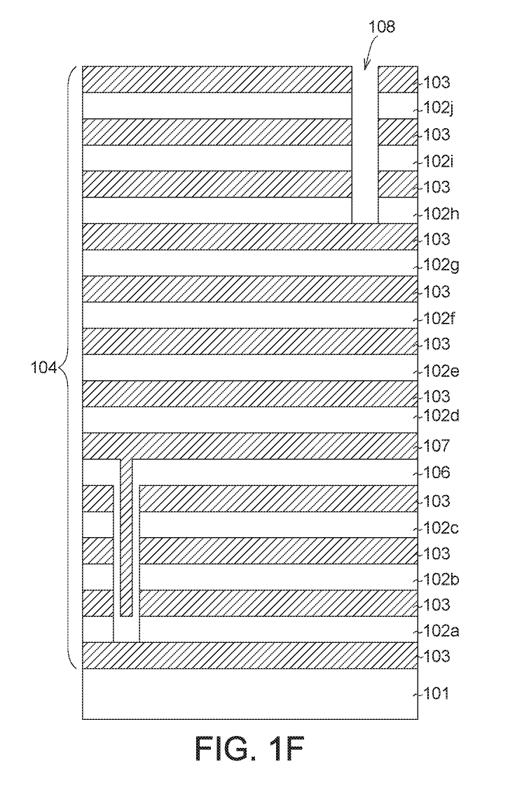

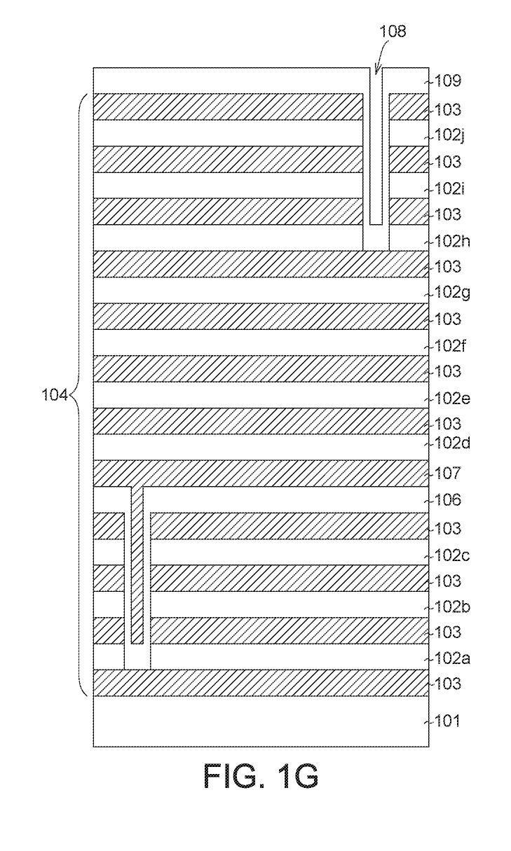

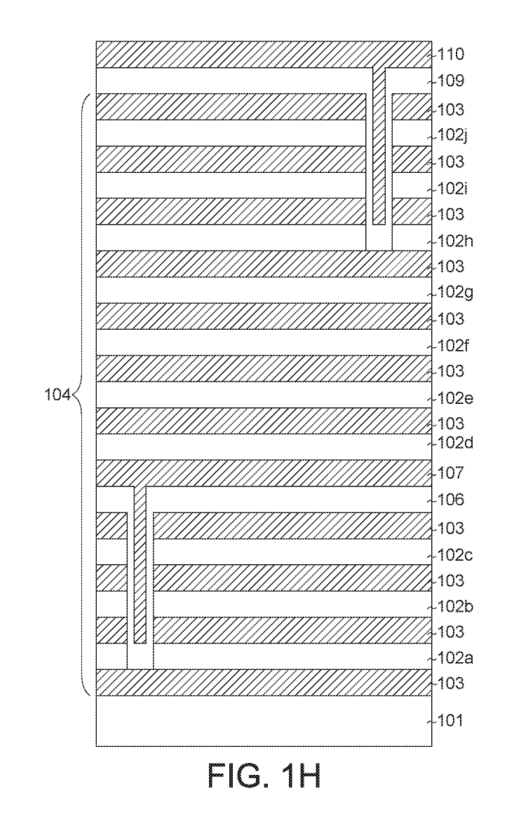

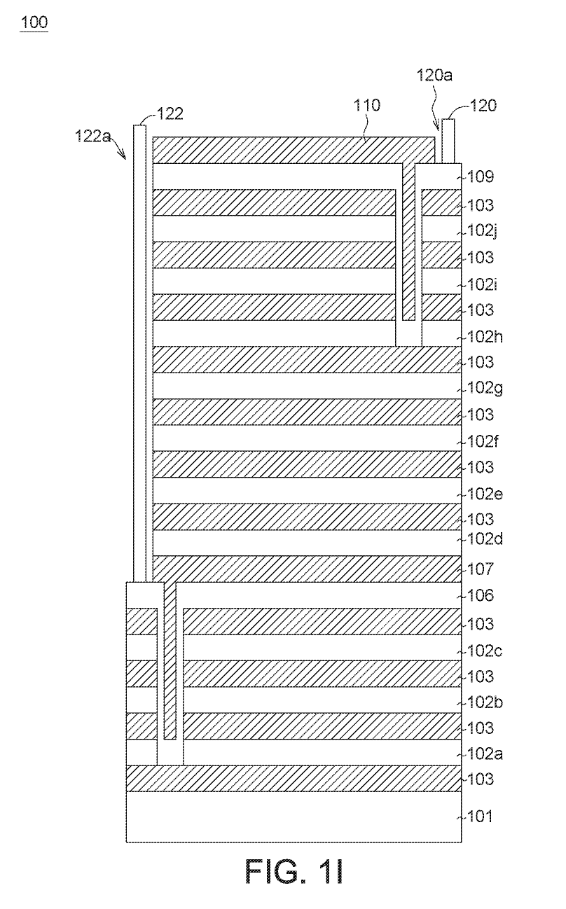

FIGS. 1A to 1I are cross-sectional views illustrating a method for forming a 3D memory device in accordance with one embodiment of the present disclosure. The method for forming the 3D memory device includes steps as follows: Firstly, a partial multi-layer stack 104′ including a plurality of conductive layers 102a, 102b and 102c is formed on a substrate 101 (see FIG. 1A).

In some embodiments of the present disclosure, the process for forming the partial multi-layer stack 104′ includes steps of performing a plurality of deposition processes, e.g. low pressure chemical vapor deposition (LPCVD), along the vertical (Z) direction to form a plurality of conductive layers 102a, 102b and 102c and insulating layers 103 alternatively stacked with each other. The conductive layers 102a, 102b and 102c are insulated from one another by one of the insulating layers 103 and have a substantially the same thickness.

Next, the partial multi-layer stack 104′ is patterned to form at least one opening extending into therein. In some embodiments of the present disclosure, an anisotropic etching process, such as a reactive ion etching (RIE), is performed to form a opening 105 in the partial multi-layer stack 104′ and penetrating through the conductive layers 102a, 102b and 102c (see FIG. 1B).

The width W of the opening 105 can be less than or equal to twofold of the product of the average thickness T of the conductive layers 102a, 102b and 102c and a conformal ratio r (W≤2×r×T). Wherein the conformal ratio r is a constant predetermined by the design requirements and process window of the 3D memory device 100. However, the size of the openings 105a and 105b may not be limited to this regards, in some other embodiments of the present disclosure, the width W of the openings 105a and 105b can be greater than twofold of the product of the average thickness T of the conductive layers 102a, 102b and 102c and a conformal ratio r (W≥2×r×T).

A contact layer 106 is then formed in the opening 105 and electrically connecting the conductive layers 102a, 102b and 102c that are penetrated by the opening 105. In some embodiments of the present disclosure, the contact layer 106 is formed by a selective deposition process. The contact layer 106 at least covers on the bottoms and sidewalls of these opening 105 and electrically connecting the conductive layers 102a, 102b and 102c. The contact layer 106 can be made of metal element, alloys, poly-silicon, metal oxides or other suitable conductive materials. In the present embodiment, the contact layer 106 extends outwards and beyond the openings 105a and 105b from the bottom of the openings 105a and 105b. A portion of the contact layer 106 covers on the top surface of the insulating layer 103 which is disposed on the highest level of the partial multi-layer stack 104′. The portion of the contact layer 106 covering on the top surface of the insulating layer 103 has a thickness substantially equal to that of the conductive layers 102a, 102b and 102c (see FIG. 1C).

A dielectric material 107 is deposited on the contact layer 106 to fill the opening 105. In some embodiments of the present disclosure, In some embodiments of the present disclosure, an excess amount of the dielectric material 107 can be firstly deposited on the partial multi-layer stack 104′, and a portion of the dielectric material 107 removed by a planzrization process, such as a chemical mechanical polish (CMP), so as to make the portion of the dielectric material 107 deposited on the partial multi-layer stack 104′ has a thickness substantially equal to the average thickness of the insulating layers 103 (see FIG. 1D).

Thereinafter a plurality of conductive layers 102d, 102e, 102f, 102g, 102h, 102i and 102j as well as a plurality of insulating layers 103 are formed on the polished dielectric material 107 to form a multi-layer stack 104. In some embodiments of the present disclosure, the process for forming the multi-layer stack 104 includes steps as follows: A plurality of deposition processes, e.g. LPCVD, along the vertical (Z) direction to form a plurality of conductive layers 102d, 102e, 102f, 102g, 102h, 102i and 102j and insulating layers 103 alternatively stacked with each other. The conductive layers 102d, 102e, 102f, 102g, 102h, 102i and 102j are insulated from one another by one of the insulating layers 103. In the present embodiment, the structure (e.g. thickness) and material of the conductive layers 102d, 102e, 102f, 102g, 102h, 102i and 102j are identical to that of the conductive layers 102a, 102b and 102c (see FIG. 1E).

Next, the multi-layer stack 104 is the patterned to form at least one opening extending into therein. In some embodiments of the present disclosure, an anisotropic etching process, such as a RIE, is performed to form an opening 108 in the multi-layer stack 104 and penetrating through the conductive layers 102h, 102i and 102j that are disposed at the most top levels of the multi-layer stack 104 (see FIG. 1F).

A contact layer 109 is then formed in the opening 108 and electrically connecting the conductive layers 102a, 102h, 102i and 102j that are penetrated by the opening 108. In some embodiments of the present disclosure, the contact layer 109 is formed by a selective deposition process. The contact layer 109 at least covers on the bottoms and sidewalls of the opening 108 and electrically connecting the conductive layers 102h, 102i and 102j. The contact layer 109 can be made of metal element, alloys, poly-silicon, metal oxides or other suitable conductive materials. In the present embodiment, the contact layer 109 extends outwards and beyond the opening 108 from the bottom of the opening 108. A portion of the contact layer 109 covers on the top surface of the insulating layer 103 which is disposed on the highest level of the multi-layer stack 104, and the portion of the contact layer 109 has a thickness substantially equal to that of the conductive layers 102h, 102i and 102j (see FIG. IG).

A dielectric material 110 is then deposited on the contact layer 109 to fill the opening 108. In some embodiments of the present disclosure, an excess amount of the dielectric material 110 can be firstly deposited on the multi-layer stack 104, and a portion of the dielectric material 110 are then removed by a planzrization process, such as a CMP, so as to make the portion of the dielectric material 110 deposited on the multi-layer stack 104 has a thickness substantially equal to the average thickness of the insulating layers 103 (see FIG. 1H).

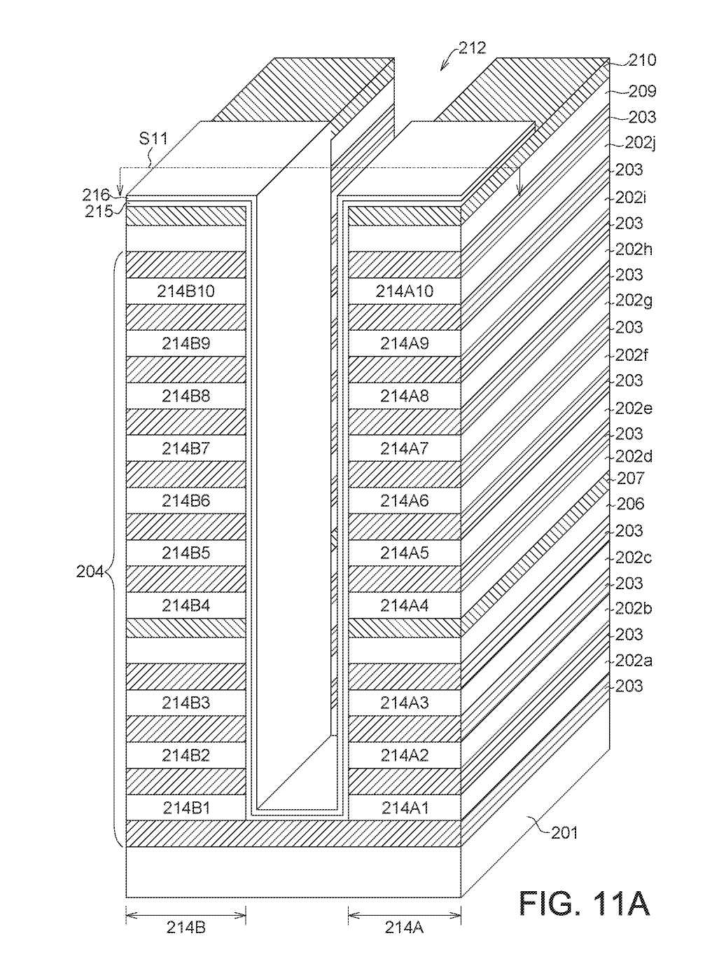

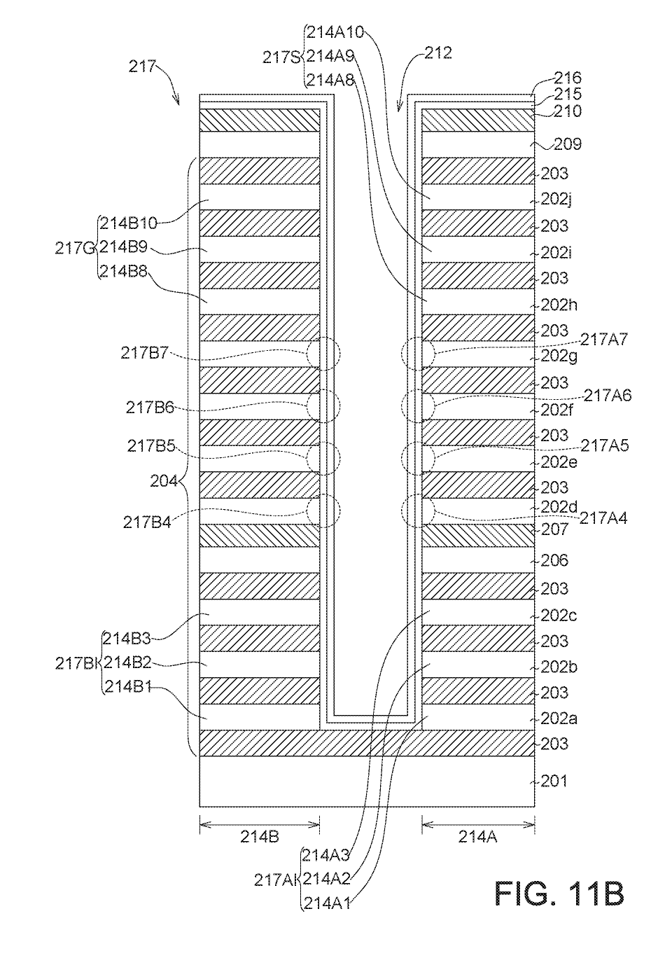

Contact plugs 120 and 122 are respectively formed on the contact layers 106 and 109. In some embodiments of the present disclosure, forming the contact plugs 120 and 122 includes steps as follows: Etching processes respectively using the contact layers 109 and 106 as the etching stop layers are preferred to form a through hole 120a passing through the dielectric material 110 and a through hole 122a passing through the dielectric material 110 and 107, the conductive layers 102d, 102e, 102f, 102g, 102h, 102i and 102j and the insulating layer 103 to expose portions of the contact layer 109 and 106 respectively. A conductive material, such as metal (Al, Cu, W, Au, Ag, Pt or a combination of two or more of these materials), are filled in the openings 120a and 122a (see FIG. 11).

Subsequently, pluralities of downstream-processes are performed to form a transistor unit on each of the conductive layers 102a-102j, so as to configure the 3D memory device 100. Wherein the conductive layers 102a-102j serve as the gates of the corresponding transistor units. In the present embodiment, the gates of the transistor units that are formed on the conductive layers 102h, 102i and 102j disposed on the top portion of the multi-layer stack 104 are electrically connected in parallel by the contact layer 109, and the electrically connected transistor units can be integrated to serve as a SSL switch or a GSL switch of the 3D memory device 100. The gates of the transistor units that are to ed on the conductive layers 102a, 102b and 102c disposed on the bottom portion of the multi-layer stack 104 are connected in parallel by the contact layer 106, and the electrically connected transistor units can be integrated to serve as an IG switch or a GSL switch of the 3D memory device 100.

In some embodiments of the present disclosure, the 3D memory device 100 may be a single-gate vertical channel (SGVC) memory device, such as a 3D NAND flash memory device. However, in some other embodiments, the 3D memory device 100 may not be limited to this regards. Any memory device having plurality vertical stacked transistors of which the gates are electrically connected in parallel by a contact layer may not be seen as not breaching the spirit of the invention.

A 3D NAND flash memory device and the fabricating method thereof serving as an illustrative embodiment is disclosed below. The method for forming the 3D NAND flash memory device includes steps as follows:

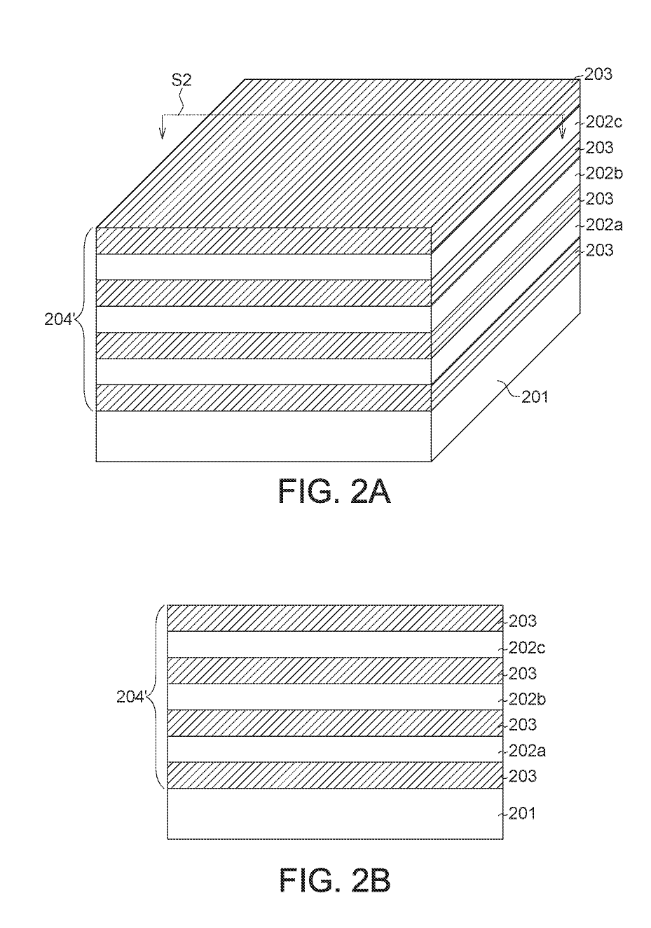

Firstly, a partial multi-layer stack 204′ including a plurality of conductive layers 202a, 202b and 202c is formed on a substrate 201. FIG. 2A is a perspective view illustrating the structure after a partial multi-layer stack 104′ is formed on the substrate 201. FIG. 2B is a cross-sectional view taken along the section line S2 of FIG. 2A.

The process for forming the partial multi-layer stack 204′ includes steps of performing a plurality of deposition processes, e.g. LPCVD, along the Z direction to form a plurality of conductive layers 202a, 202b and 202c and insulating layers 203 alternatively stacked with each other. The conductive layers 202a, 202b and 202c are insulated from one another by one of the insulating layers 203 and have a substantially the same thickness.

In some embodiments of the present disclosure, the conductive layers 202a, 202b and 202c can be made of a semiconductor material, such as n-type poly-silicon or n-type epitaxial single crystal silicon, doped with phosphorus or arsenic, p-type poly-silicon or p-type epitaxial single crystal silicon doped with boron, un-doped poly-silicon, silicide(such as, TiSi, CoSi or SiGe, oxide semiconductors (such as, InZnO or InGaZnO), metal (such as, Al, Cu, W, Ti, Co, Ni, TiN, TaN or TaAlN) or the arbitrary combinations thereof. The insulating layers 203 are made of dielectric material, such as silicon oxide, silicon nitride, silicon oxynitride silicate or other suitable materials.

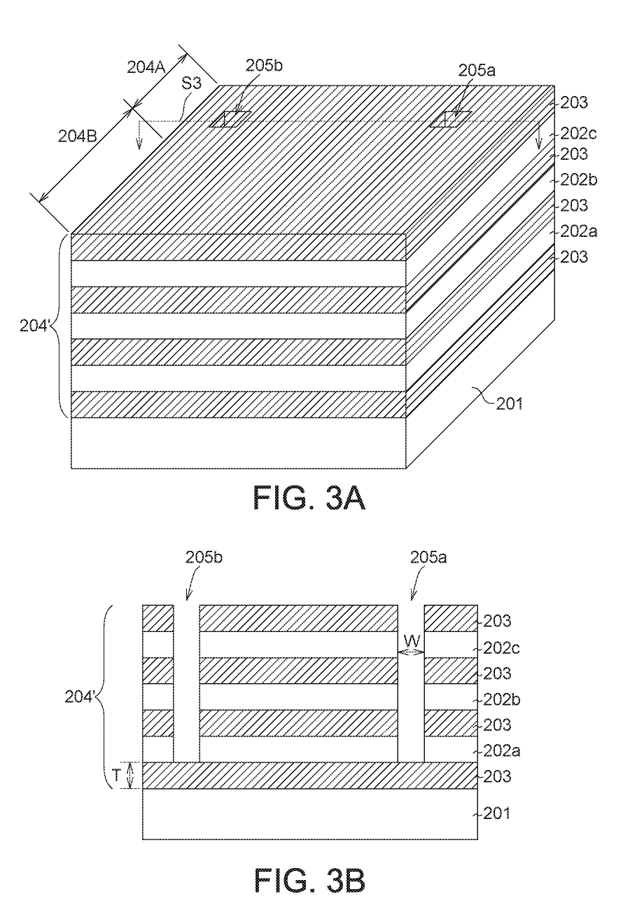

Next, the partial multi-layer stack 204′ is patterned to form at least one opening extending into therein. FIG. 3A is a prospective view illustrating the result after the process for patterning the partial multi-layer stack 204′ is performed on the structure depicted in FIG. 2A. FIG. 3B is a cross-sectional view taken along the section line S3 of FIG. 3A.

In some embodiments of the present disclosure, an anisotropic etching process, such as a RIE, is performed to form at least one opening, such as the openings 205a and 205b, in the word line pad 204A of the partial multi-layer stack 204′ and penetrating through the conductive layers 202a, 202b and 202c. In the present embodiment, the openings 105a and 105b may have a width W substantially the same.

The width W of the openings 205a and 205b can be less than or equal to twofold of the product of the average thickness T of the conductive layers 202a, 202b and 202c and a conformal ratio r (W≤2×r×T). Wherein the conformal ratio r is a constant predetermined by the design require rents and process window of the 3D memory device. However, the size of the openings 205a and 105b may not be limited to this regards, in some other embodiments of the present disclosure, the width W of the openings 205a and 205b can be greater than twofold of the product of the average thickness T of the conductive layers 202a, 202b and 202c and a conformal ratio r (W>2×r×T).

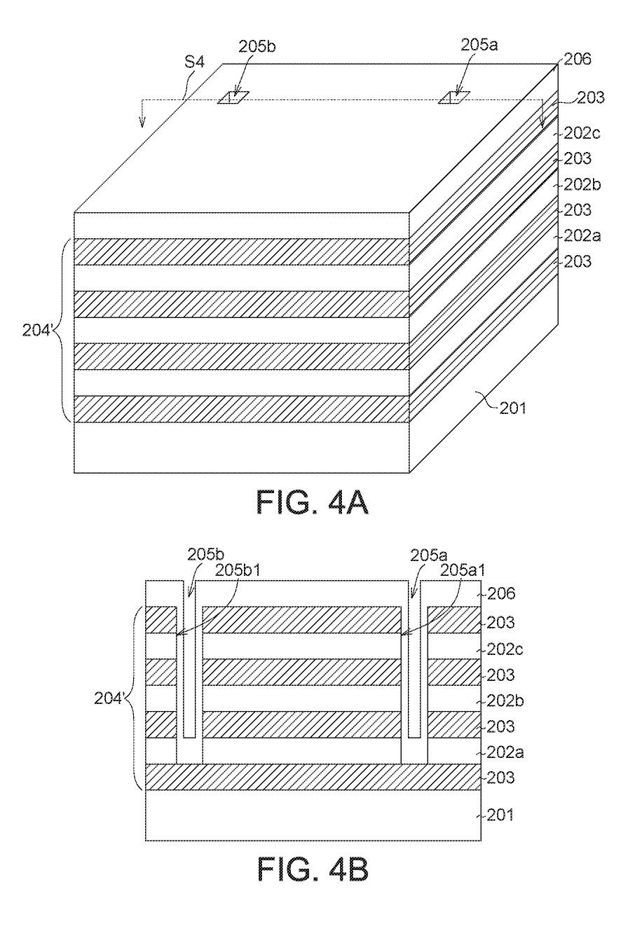

Next, a contact layer 206 is formed in the openings 205a and 205b and electrically connecting the conductive layers 202a, 202b and 202c that are penetrated by the openings 205a and 205b. FIG. 4A is a prospective view illustrating the result after the contact layer 206 is formed on the structure depicted in FIG. 3A. FIG. 4B is a cross-sectional view taken along the section line S4 of FIG. 4A.

In some embodiments of the present disclosure, the contact layer 206 is formed by a selective deposition process. The contact layer 206 at least covers on the bottoms and sidewalls of these openings 205a and 205b and electrically connecting the conductive layers 202a, 202b and 202c. The contact layer 206 can be made of metal element, alloys, poly-silicon, metal oxides or other suitable conductive materials. In the present embodiment, the contact layer 206 extends outwards and beyond the openings 205a and 205b from the bottom of the openings 205a and 105b. A portion of the contact layer 206 covers on the top surface of the insulating layer 203 which is disposed on the highest level of the partial multi-layer stack 204′. The portion of the contact layer 206 covering on the top surface of the insulating layer 203 has a thickness substantially equal to that of the conductive layers 202a, 202b and 202c.

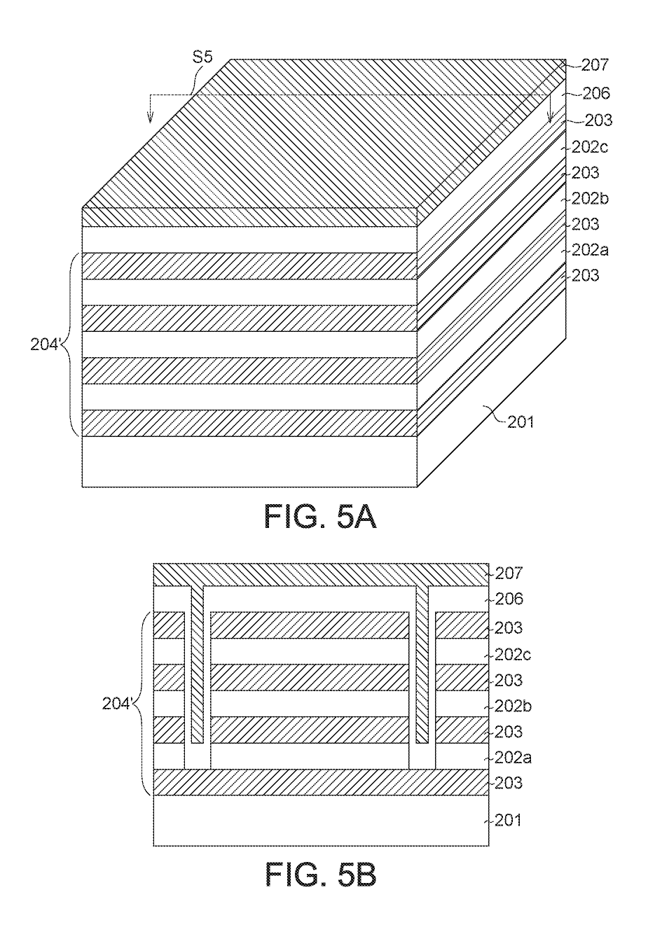

A dielectric material 207 is then deposited on the contact layer 206 to fill the openings 205a and 205b. FIG. 5A is a prospective view illustrating the result after the dielectric material 207 is deposited on the structure depicted in FIG. 4A. FIG. 5B is a cross-sectional view taken along the section line S5 of FIG. 5A.

In some embodiments of the present disclosure, excess amount of the more dielectric material 207 may be required to make sure that the openings 205a and 205b are thoroughly filled due to the bigger size (e.g. W≥2×r×T) thereof. In this case, a portion of the dielectric material 207 deposited on the partial multi-layer stack 204′ is then removed by a planzrization process, such as a CMP, so as to make the portion of the dielectric material 207 deposited on the partial multi-layer stack 204′ has a thickness substantially equal to the average thickness of the insulating layers 203.

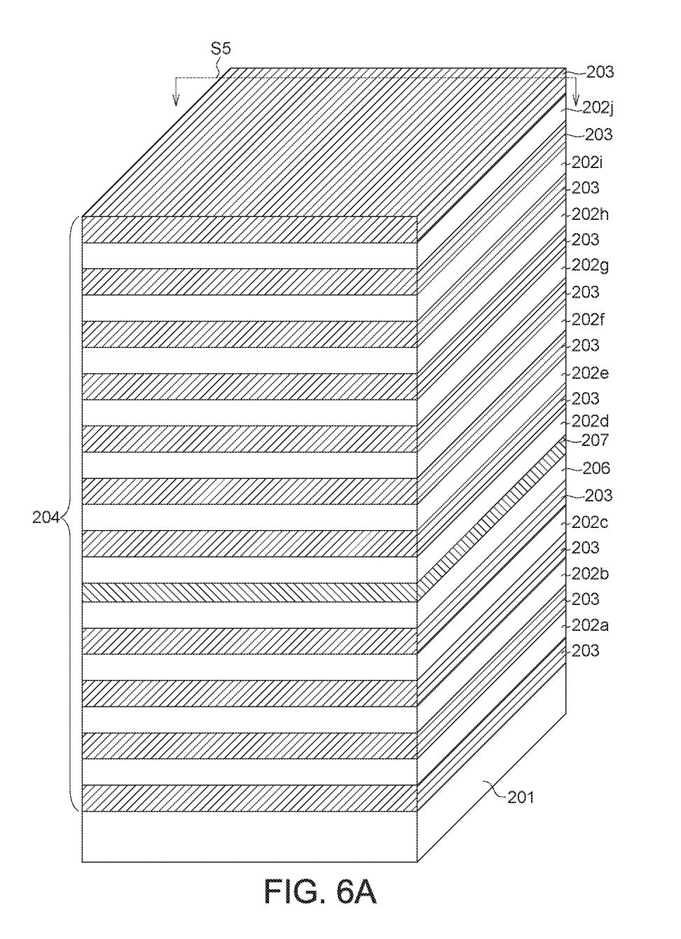

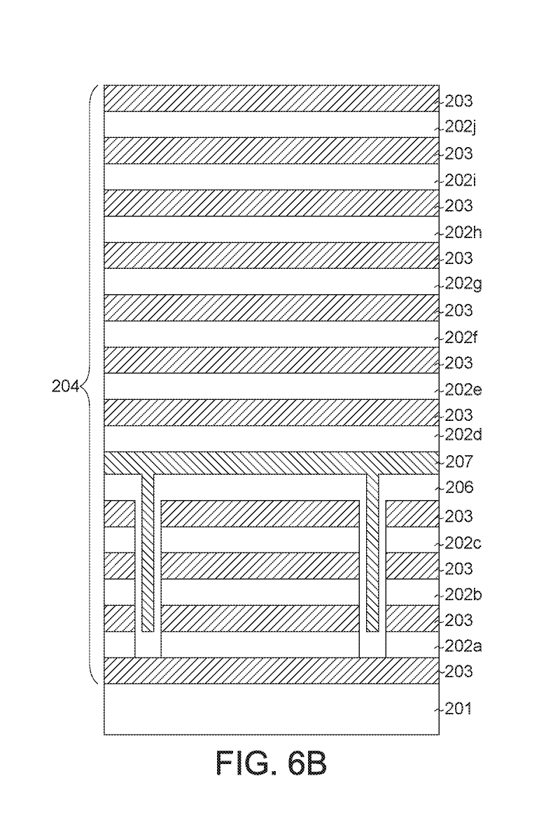

Thereinafter a plurality of conductive layers 202d, 202e, 202f, 202g, 202h, 202i and 202j as well as a plurality of insulating layers 203 are formed on the polished dielectric material 207 to form a multi-layer stack 204. FIG. 6A is a prospective view illustrating the result after the multi-layer stack 204 is formed on the structure depicted in FIG. 5A. FIG. 6B is a cross-sectional view taken along the section line S6 of FIG. 6A.

In some embodiments of the present disclosure, the process for forming the multi-layer stack 204 includes steps as follows: A plurality of deposition processes, e.g. LPCVD, along the vertical (Z) direction to form a plurality of conductive layers 202d, 202e, 202f, 202g, 202h, 202i and 202j as well as a plurality of insulating layers 203 alternatively stacked with each other. The conductive layers 202d, 202e, 202f, 202g, 202h, 202i arid 202j are insulated from one another by one of the insulating layers 203. In the present embodiment, the structure (e.g. thickness) and material of the conductive layers 202d, 202e, 202f, 202g, 202h, 202i and 202j are identical to that of the conductive layers 202a, 202b and 202c.

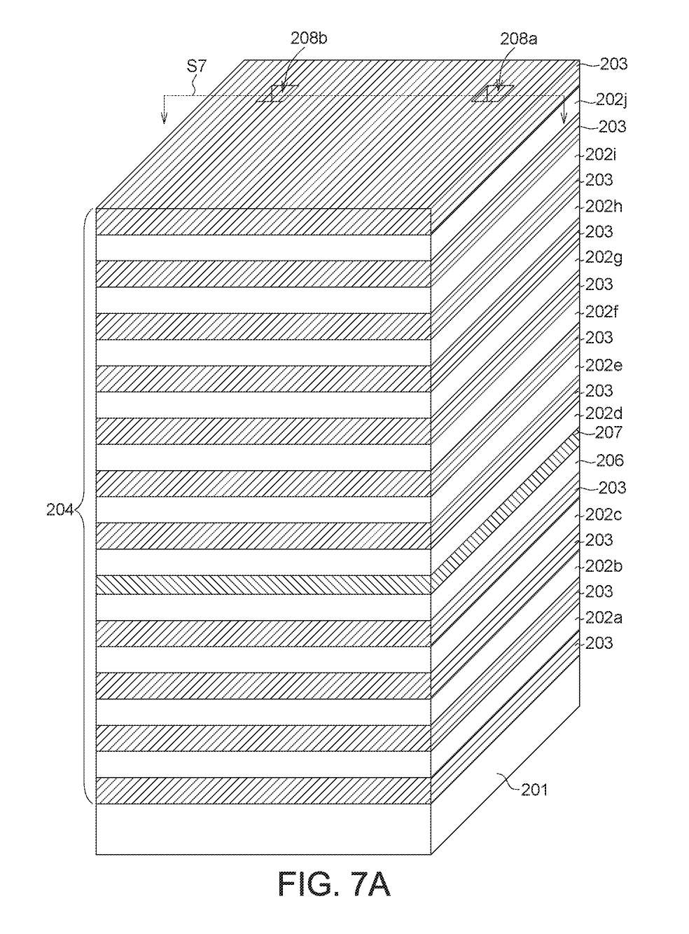

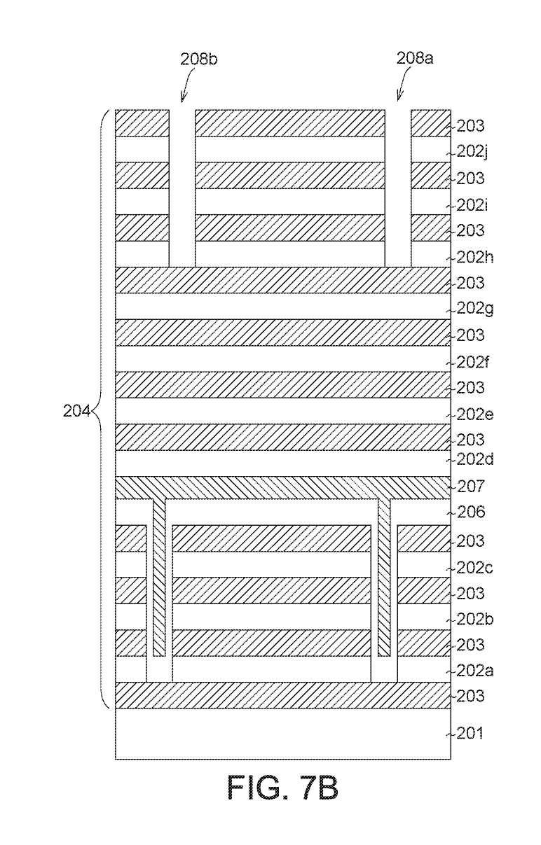

Next, the multi-layer stack 204 is the patterned to form at least one opening, such as the openings 208a and 208b extending into therein. FIG. 7A is a prospective view illustrating the result after the process for patterning the multi-layer stack 204 is performed on the structure depicted in FIG. 6A. FIG. 7B is a cross-sectional view taken along the section line S7 of FIG. 7A.

In some embodiments of the present disclosure, an anisotropic etching process, such as a RIE, is performed to form the plurality of openings 208a and 208b in the word line pad 204A of the multi-layer stack 204 and penetrating through the conductive layers 202h, 202i and 202j that are disposed at the most top levels of the multi-layer stack 204.

For the purpose for description convenience, in the present embodiment, the openings 208a and 208b do not align the openings 205a and 205b; and the size of the openings 208a and 208b may identical to that of the openings 105a and 105b. However, in some other embodiments, the openings 108a and 208b may align the openings 205a and 205b. The size of the openings 208a and 208b may be different from that of the openings 205a and 205b.

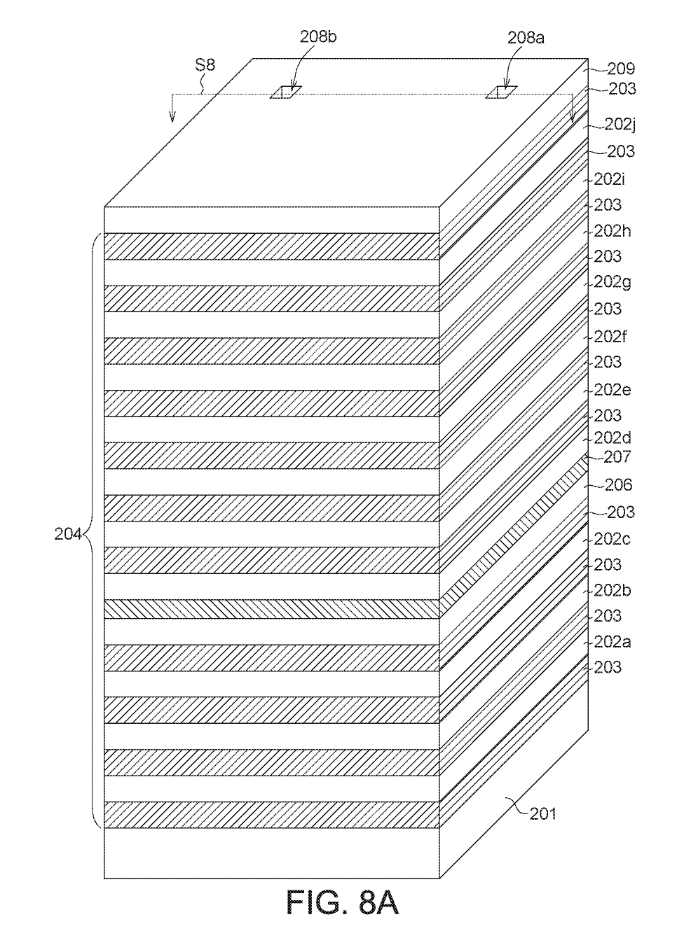

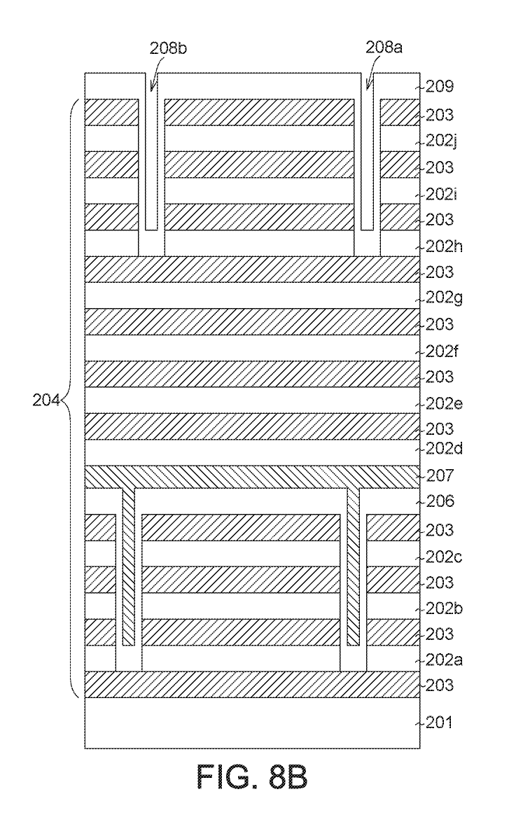

A contact layer 209 is then formed in the openings 208a and 208b and electrically connecting the conductive layers 202a, 202h, 202i and 202j that are penetrated by the openings 208a and 208b. FIG. 8A is a prospective view illustrating the result after the contact layer 209 is formed on the structure depicted in FIG. 7A. FIG. 8B is a cross-sectional view taken along the section line S8 of FIG. 8A.

In some embodiments of the present disclosure, the contact layer 809 is formed by a selective deposition process. The contact layer 809 at least covers on the bottoms and sidewalls of these openings 208a and 208b and electrically connecting the conductive layers 202h, 202i and 202j. The contact layer 209 can be made of metal element, alloys, poly-silicon, metal oxides or other suitable conductive materials. In the present embodiment, the contact layer 209 extends outwards and beyond the openings 208a and 208b from the bottom of the openings 208a and 208b. A portion of the contact layer 209 covers on the top surface of the insulating layer 203 which is disposed on the highest level of the multi-layer stack 204. The portion of the contact layer 209 covering on the top surface of the insulating layer 203 has a thickness substantially equal to that of the conductive layers 202h, 202i and 202j.

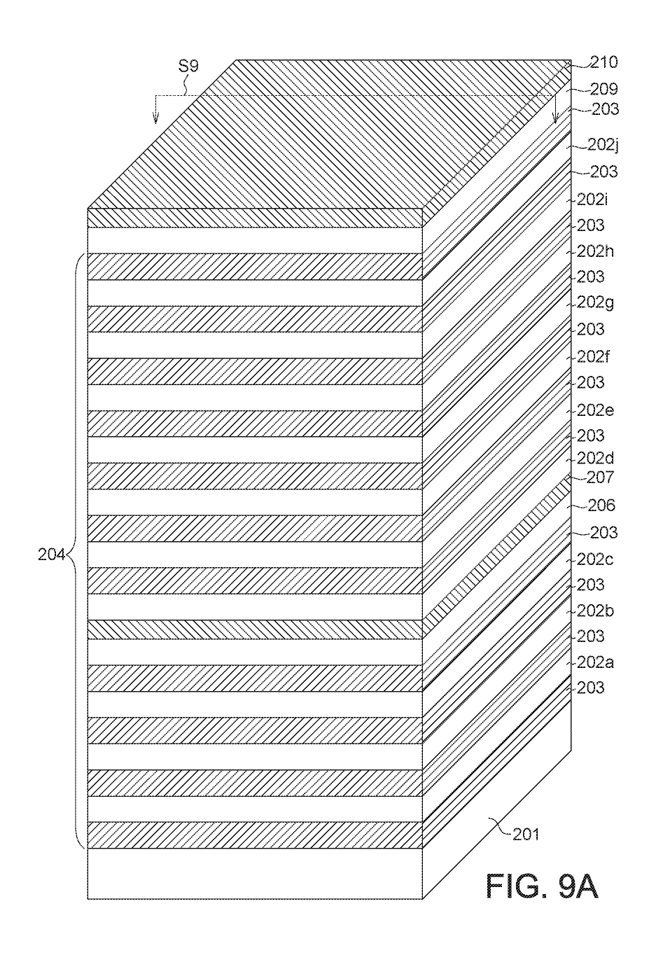

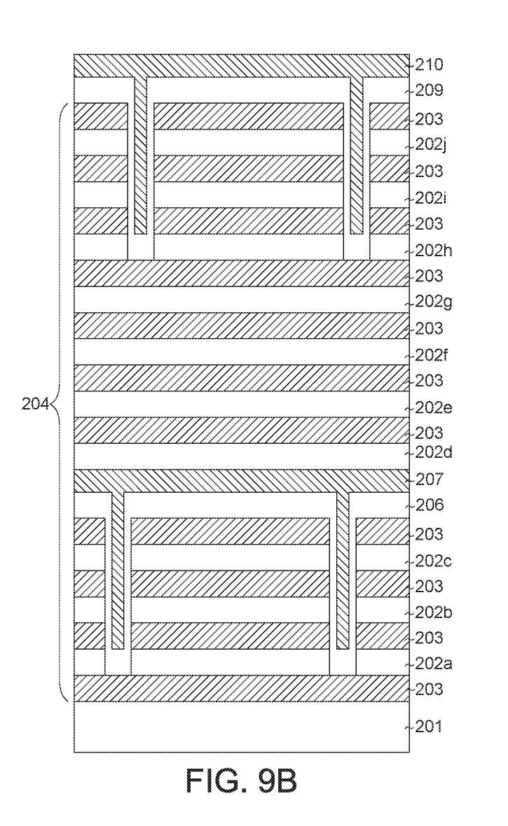

A dielectric material 210 is then deposited on the contact layer 209 to fill the openings 208a and 208b. FIG. 9A is a prospective view illustrating the result after the dielectric material 210 is deposited on the structure depicted in FIG. 8A. FIG. 9B is a cross-sectional view taken along the section line S9 of FIG. 9A.

In some embodiments of the present disclosure, excess amount of the more dielectric material 110 may be required to make sure that the openings 208a and 208b are thoroughly filled due to the bigger size (e.g. W>2×r×T) thereof. In this case, a portion of the dielectric material 210 deposited on the multi-layer stack 204 may be removed by a planzrization process, such as a CMP, so as to make the portion of the dielectric material 210 deposited on the multi-layer stack 204 has a thickness substantially equal to the average thickness of the insulating layers 203.

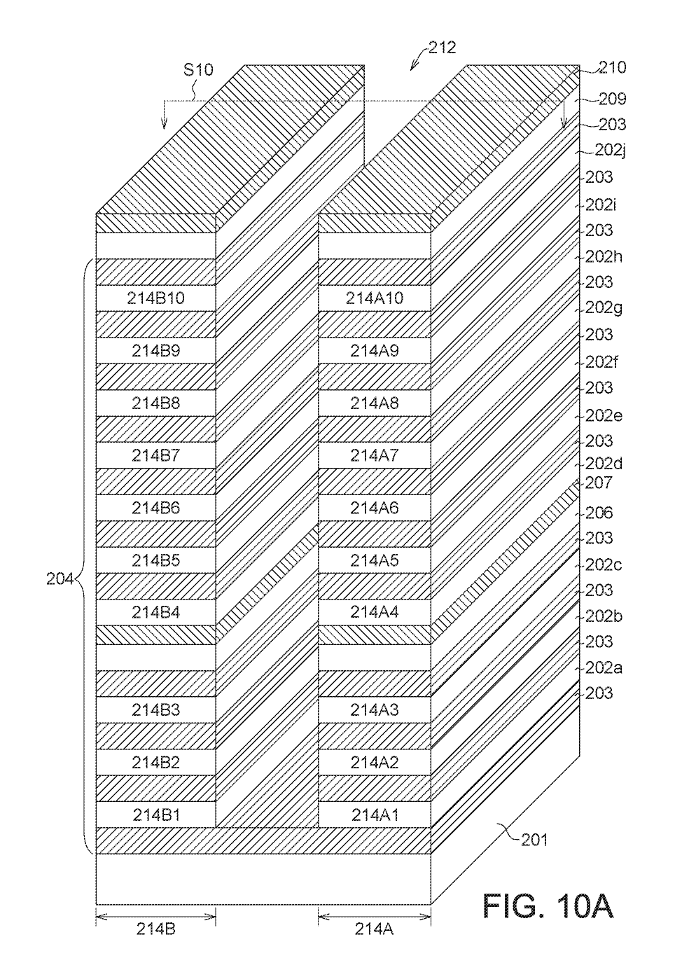

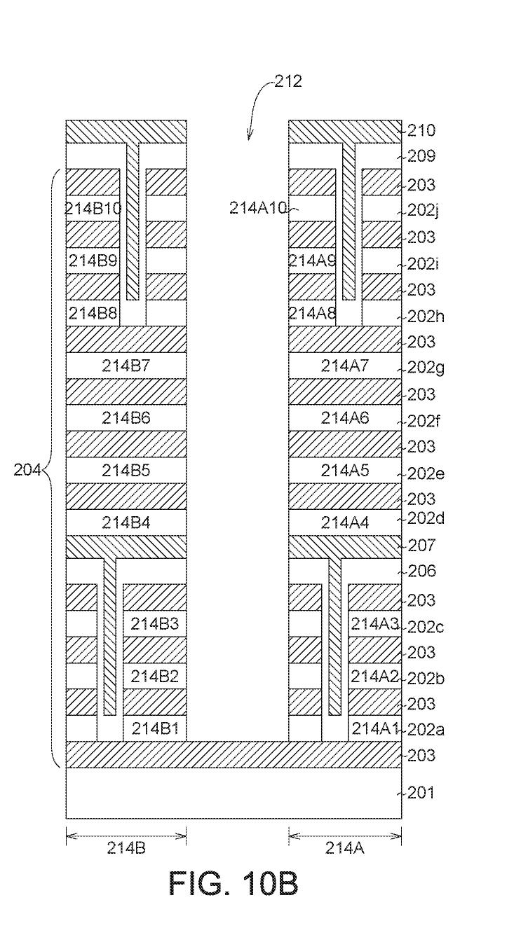

Subsequently, at least one vertical channel memory cell string is formed in the multi-layer stack 204. The method for forming the vertical channel memory cell string includes steps as follows: Firstly at least one trench 212 is formed to divide the multi-layer stack 204 into a plurality of ridge (-shaped) stacks 214A and 214B. FIG. 10A is a prospective view illustrating the result after a plurality of trenches 212 are formed on the structure depicted in FIG. 9A. FIG. 10B is a cross-sectional view taken along the section line S10 of FIG. 10A,

In some embodiments of the present disclosure, an anisotropic etching process, such as a RIE process is performed on the multi-layer stack structure 204 to form a plurality of trenches 212 in the multi-layer stack structure 204 laterally extending along an X direction and vertically extending along the Z direction, so as to divide the multi-layer stack structure 204 into ridge stacks 214A and 214B, and to expose a portion of the bottom-most insulating layer 103 from the trenches 212.

Each of the ridge stacks 214A and 214B includes a plurality of conductive strips. For example, in the present embodiment, the ridge stack 214A includes conductive strips 214A1-214A10 stacked upwards along the Z direction; and the ridge stack 214B includes conductive strips 214B1-214B10 stacked upwards along the Z direction.

Wherein the conductive strips 214A1 and 214B1 that are respectively disposed on the bottom levels of the ridge stacks 204A and 204B are configured by the patterned conductive layer 202a; the conductive strips 214A2 and 214B2 of the ridge stacks 204A and 204B are configured by the patterned conductive layer 202b; the conductive strips 214A3 and 214B3 of the ridge stacks 204A and 204B are configured by the patterned conductive layer 202c; the conductive strips 214A4 and 214B4 of the ridge stacks 204A and 204B are configured by the patterned conductive layer 202d; the conductive strips 214A5 and 214B5 of the ridge stacks 204A and 204B are configured by the patterned conductive layer 202e; the conductive strips 214A6 and 214B6 of the ridge stacks 204A and 204B are configured by the patterned conductive layer 202f; the conductive strips 214A7 and 214B7 of the ridge stacks 204A and 204B are configured by the patterned conductive layer 202g; the conductive strips 214A8 and 214B8 of the ridge stacks 204A and 204B are configured by the patterned conductive layer 202h; the conductive strips 214A9 and 214B9 of the ridge stacks 204A and 204B are configured by the patterned conductive layer 202i; and the conductive strips 214A10 and 214B10 that are respectively disposed on the bottom level of the ridge stacks 204A and 204B are configured by the patterned conductive layer 202j.

The conductive strips 214A1, 214A2 and 214A3 of the ridge stack 204A are electrically connected with each other by a portion of the patterned contact layer 206; and the conductive strips 214B1, 214B2 and 214B3 of the ridge stack 204B are electrically connected with each other by another portion of the patterned contact layer 206. The conductive strips 214A8, 214A9 and 214A10 of the ridge stack 204A are electrically connected with each other by a portion of the patterned contact layer 109; and the conductive strips 214B8, 214B9 and 214B10 of the ridge stack 204B are electrically connected with each other by another portion of the patterned contact layer 209.

Thereafter, a memory material layer 215 and a channel layer 216 are formed in sequence to cover the ridge stacks 214A and 214B. FIG. 11A is a prospective view illustrating the result after the memory material layer 215 and the channel layer 216 are formed on the structure depicted in FIG. 10A. FIG. 11B is a cross-sectional view taken along the section line S11 of FIG. 11A. In some embodiments of the present disclosure, a deposition process is performed to form a memory material layer 215 a charge trapping structure on the sidewalls of the ridge stacks 214A and 214B. A patterned semiconductor channel layer 216 is then formed over the memory material layer 215, so as to form a plurality of transistor units 217A4-217A7 and 217B4-217B7 at the cross points of the memory material layer 215, the patterned semiconductor channel layer 216 and the conductor strips 214A1-214A7 and 214B1-214B7 involve in the ridge stacks 214A and 214B.

In some embodiment of the present disclosure, the charge trapping structure may be a stack of composite layers which is selected from a group consisting of oxide-nitride-oxide (ONO), oxide-nitride-oxide-nitride-oxide (ONONO), silicon-oxide-nitride-oxide-silicon (SONOS), band gap engineered silicon-oxide-nitride-oxide-silicon (BE-SONOS), tantalum nitride, aluminum oxide, silicon nitride, silicon oxide, silicon (TANOS) and metal-high-k band gap-engineered silicon-oxide-nitride-oxide-silicon (MA BE-SONOS). The patterned semiconductor channel layer 116 can be made of n type poly-silicon or n type single crystal epitaxial silicon doped with n type dopants (e.g. phosphorus or arsenic) or can be made of p type poly-silicon or single crystal epitaxial silicon doped with p type dopants (e.g. boron).

In the present embodiment, the patterned semiconductor channel layer 216 is an n type poly-silicon layer including at least two portions separated with each other. One portion of the patterned semiconductor channel layer 216 covers on the sidewalls of the ridge stacks 214A and 214B and the bottom of the trench 212 and serves as a channel film connecting the transistor units 217A4-217A7 and 217B4-217B7 formed on the sidewalls of the ridge stacks 214A and 214B in series, so as to form a U-shaped memory cells string 217.

To take the U-shaped memory cells string 217 as an example, the conductive strips 214A1, 214A2 and 214A3 formed at the bottom levels of the ridge stack 214A and the conductive strips 214B1, 214B2 and 214B3 formed at the bottom levels of the ridge stack 214B are electrically connected with each other by the patterned contact layer 206; and the two set of transistor units that are connected by the patterned contact layer 106 can serve as the IG switches 217AI and 217BI of the U-shaped memory cells string 217 respectively. The conductive strips 214A8, 214A9 and 214A10 formed at the highest levels of the ridge stack 214A are electrically connected with each other by a portion of the patterned contact layer 209 can serve as the SSL switch 217S of the U-shaped memory cells string 217. The conductive strips 214B8, 214B9 and 214B10 formed at the highest levels of the ridge stack 214B are electrically connected with each other by another portion of the patterned contact layer 209 can serve as the GSL switch 217G of the U-shaped memory cells string 217.

After the U-shaped memory cells string 217 is formed, a dielectric material (not shown) is filled into the trenches 212. In some embodiments of the present disclosure, the dielectric material 119 may be made of silicon oxide, silicon nitride, silicon oxynitride, high dielectric constant (high-k) materials or the arbitrary combinations thereof.

It should be appreciated that the structure as depicted in FIGS. 11A and 11B is just illustrated. Although merely one U-shaped memory cells string 217 formed on two ridge stacks 214A and 214B are described, the 3D memory device may include more ridge stacks and U-shaped memory cells strings to form a 3D memory cell array. In the present embodiment, the openings 208a and 208b and the contact layer 209 are formed prior to the process for forming of the U-shaped memory cells string 217.

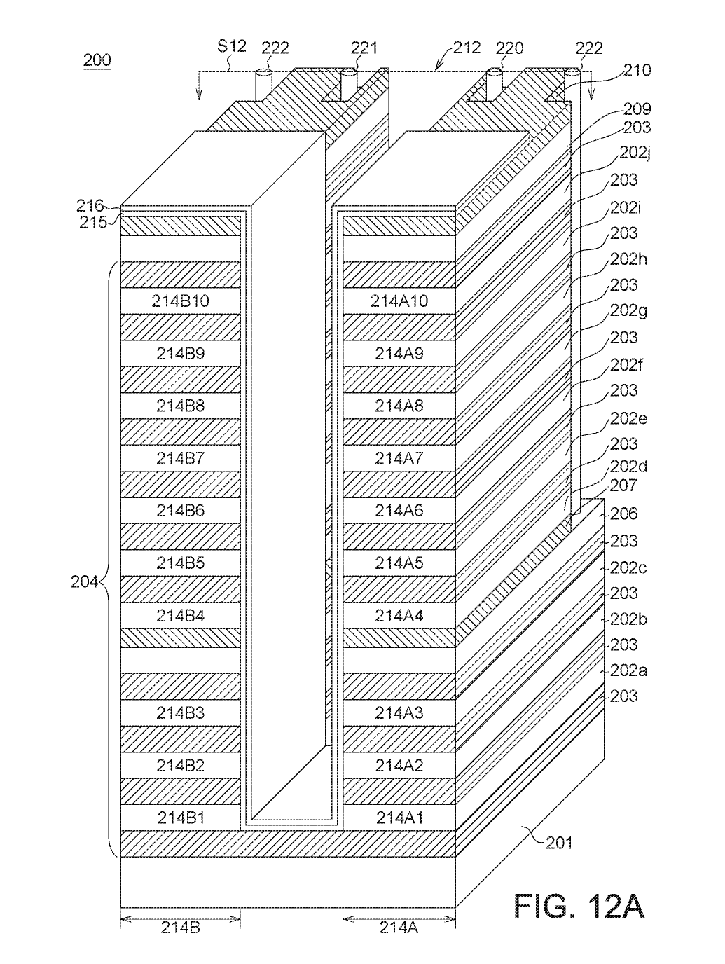

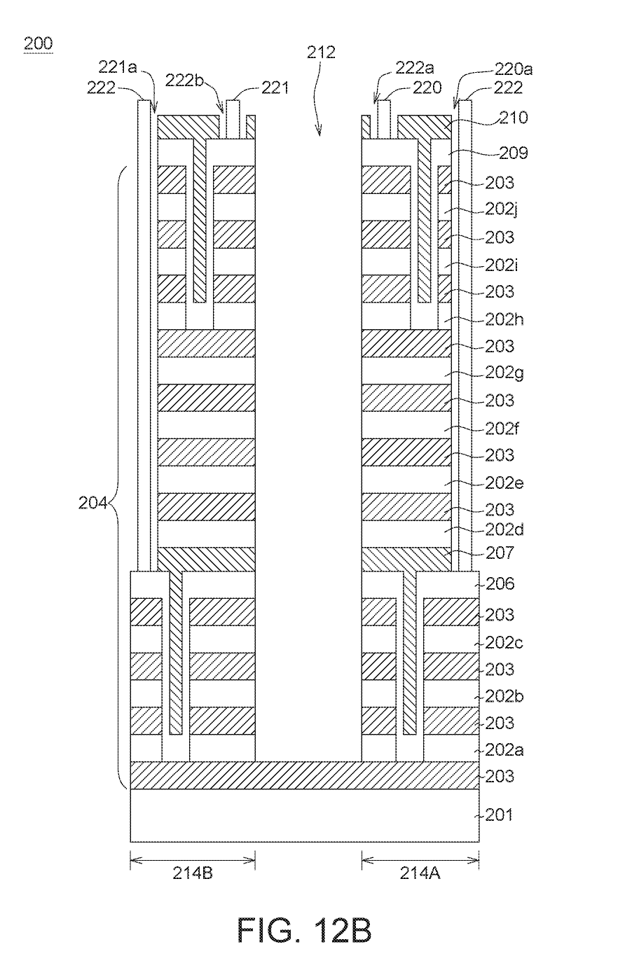

FIG. 12A is a prospective view illustrating the result after a plurality of SSL contact plugs 220, GSL contact plugs 221, and IG contact plug 222 are formed on the structure depicted in FIG. 11A. FIG. 12B is a cross-sectional view taken along the section line S12 of FIG. 12A.

In some embodiments of the present disclosure, forming the SSL contact plugs 220, GSL contact plugs 221, and IG contact plug 222 includes steps as follows: An etching processes using the contact layers 209 as the etching stop layers is preferred to form a plurality through holes 222a and 222b passing through the dielectric material 210 and the insulating layer 203 disposed on the ridge stacks 214A and 214B, so as to expose a portion of the contact layer 209: and another etching processes using the contact layers 206 as the etching stop layers is performed to form a plurality through holes 220a and 221 a passing through the dielectric material 210 and 207, the conductive layers 202d, 202e, 202f, 202g, 202h, 202i, 202j and 209 and the insulating layer 203 disposed on the ridge stacks 214A and 214B to expose a portion of the contact layer 206. A conductive material, such as metal (Al, Cu, W, Au, Ag, Pt or a combination of two or more of these materials), are filled in the opening 220a, 221a, 222a and 222b.

Subsequently, at least one bit line, a common source line, a control line (not shown) are formed on the ridge stacks 214A and 214B to connect the SSL contact plugs 220, GSL contact plugs 221, and IG contact plug 222 of the U-shaped memory cells string 217. A plurality of stair-shaped word line contacts (not shown) are formed on the word line pad 204A to make the conductive strips 214A4-214A7 and 214B4-214B7 of the ridge stacks 214A and 214B in contact with different word lines (not shown)respectively. After a plurality of downstream processes are carried out the 3D memory device 200 is produced.

Since the SSL switch 217S, the GSL switch 217G and the IG switches 217AI and 217BI are respectively configured by a set of transistor units (i.e. the transistor units 217A8-217A1, 217B8-217B10, 217A1-217A3 and 217B1-217B3) formed on the U-shaped memory cells string 217 connected by the patterned contact layer 206 and 209 in parallel, thus the SSL switch 217S, the GSL switch 217G and the IG switches 217AI and 217BI may have threshold voltages greater than that of the prior art switches. In addition, because the conductive strips 214A8-214A10, 214B8-214B10, 214A1-214A3 and 214B1-214B3 serving as the gates of the SSL switch 2175, the GSL switch 217G and the IG switches 217AI and 217BI are formed by the patterned conductive layers 202a-202c and 202h-202j; and the conductive strips 214A4-214A7 and 214B4-214B7 serving as the gates of the other memory cells of the of the U-shaped memory cells string 217 are formed by the patterned conductive layers 202d-202g. The gates of the SSL switch 217S, the GSL switch 217G and the IG switches 217AI and 217BI as well as the gates of the memory cells of the of the U-shaped memory cells string 217 can be formed by common deposition process. Such that the manufacturing process of the 3D memory device 200 can be simplified, and the manufacturing cost and time can be reduced.

In the present embodiment, each of the SSL switch 2175, the GSL switch 217G and the IG switches 217AI and 217BI requires only one contact plug, such as the SSL contact plugs 220, the GSL contact plugs 221, or the IG contact plug 222, to be connected with the bit line, the common source line or the control line (not shown), nevertheless the SSL switch 217S, the GSL switch 217G and the IG switches 217AI and 217E are respectively constituted by a set of the conductive strips (i.e. the sets of conductive strips 214A8-214A10, 214B8-214B10, 214A1-214A3 and 214B1-214B3) formed on different levels of the conductive layers 202a-202c and 202h-202j. It is because of the factor that each set of the conductive layers 202a-202c and 202h-202j used to constitute the SSL switch 217S, the GSL switch 217G and the IG switches 217AI and 217BI is integrated into an assembled structure either by the patterned contact layer 206 or by the patterned contact layer 209. Additional contact structures that are used to respectively connect the conductive layers 202a-202c and 202h-202j to the bit line, the common source line or the control line (not shown) are no longer necessary. The circuit wiring of the 3D memory device 200 can be also simplified.

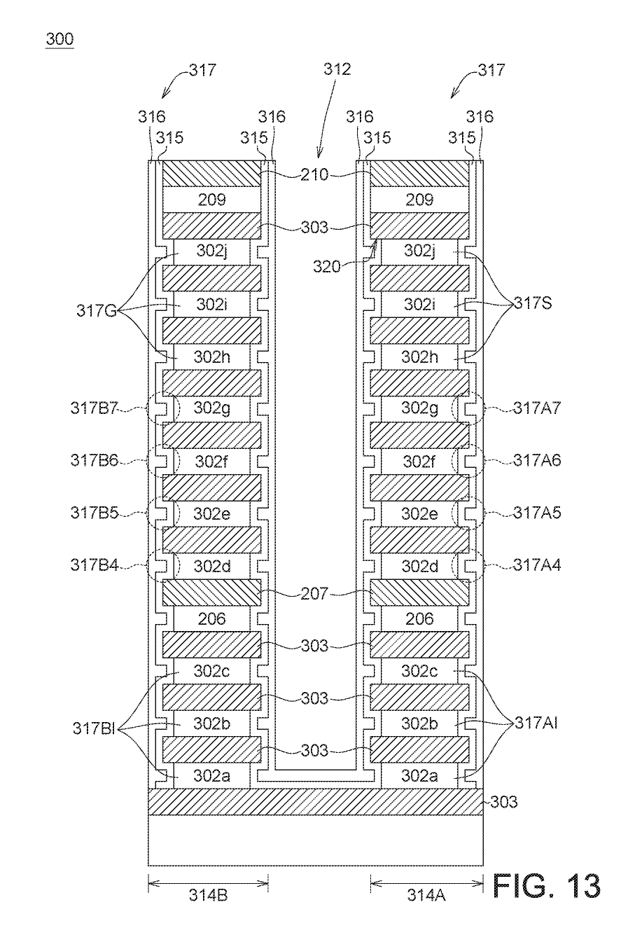

FIG. 13 is a cross-sectional view illustrating the partial structure of a 3D NAND memory device 300 according to another embodiment of the present disclosure. In the present embodiment, the memory layer 315 of the 3D memory device 300 extends into recesses 320 defined by the conductive layers 302a-302j and the insulating layers 303. The process form forming the 3D NAND memory device 300 includes steps of performing an etching back process prior to the forming of the memory layer 315 to remove the portions of the conductive layers 302a-302j, so as to define a plurality of recess 320 between each two adjacent ones of the insulating layers 103. Subsequently, the memory layer 315 is formed in the trench 312 and at least partially extends into the recesses 320. Next, a channel layer 316 is formed on the memory layer 315 to define a plurality transistor units 317A4-317A7 and 317B4-317B7 at the cross points of the channel layer 316, the memory layer 315 and the conductive layers 302d-302g of the ridge stacks 314A and 314B, and pluralities of downstream-processes (not shown) are then performed to configure the 3D memory device 300.

The set of transistor units 317A4, 317A5, 317A6 and 317A7 formed at the middle levels of the ridge stack 314A may serve as the memory cells of one memory cells string 317; and the set of transistor units 317B4, 317B5, 317B6 and 317B7 formed at the middle levels of the ridge stack 314B may serve as the memory cells of another memory cells string 317. The portions of conductive layers 302a, 302b and 302c formed at the bottom levels of the ridge stacks 314A are electrically connected with each other by a patterned contact layer 206 to serve as an IG switches 317AI of one memory cells string 317; and the portions of transistor units conductive layers 302a, 302b and 302c formed at the bottom levels of the ridge stack 314B are also electrically connected with each other by a patterned contact layer (not shown) to serve as an IG switch 317BI of another memory cells string 317 The portions of conductive layers 302h, 302i and 302j formed at the highest levels of the ridge stack 314A are respectively connected with each other by another patterned contact layer (not shown) to serve as a SSL switch 317S of one memory cells string 317; and the portions of conductive layers 302h, 302i and 302j, the patterned contact layers 206 and 209 formed at the highest levels of the ridge stack 314B are electrically connected with each other by yet another patterned contact layer 209 to serve as a GSL switch 317G of another memory cells string 317.

As discussed above, since the gates of the SSL switch 317S, the GSL switch 317G and the IG switches 317AI and 317BI as well as the gates of the memory cells of the of the memory cells strings 317 are formed by the patterned conductively layers 302a-302j which can be formed by the same deposition process, thus the gates thereof may have a substantially identical thickness, the depth of the recesses 320 resulted from the subsequent etching back process may not deviate from standard, and the yield of the 3D memory device 200 can be improved.

In accordance with the aforementioned embodiments of the present disclosure, a 3D memory device and the method for fabricating the same are provided., wherein at least one vertical channel memory cell array having a plurality transistor units is formed in a multi-layer stack which includes a plurality of conductive layers vertical stacked and insulated with each other. At least one opening penetrating through at least two adjacent ones of the conductive layers is formed in the multi-layer stack prior to or after the forming of the vertical channel memory cell array. A contact layer is then formed in the opening to electrically connect the at least two adjacent ones of the conductive layers penetrated by the opening, so as to make the gates of the transistor units that are formed on the conductive layers penetrated by the opening have an equal potential.

In other words, the transistor units formed on the conductive layers electrically connected by the contact layer can be integrated to form an assembled switch having a greater threshold voltage and lower current leakage than that of the prior art. When the assembled switch is applied in a vertical channel memory device, the process for forming the SSL switch, the GSL switch and the IG switches as well as the process forming the memory cells of the vertical channel memory device can be carried out simultaneously. The process for forming the vertical channel NAND memory device can be simplified and the manufacturing cost can be reduced. In addition, because the conductive layers used to configure the assembled switch are electrically connected with each other, thus only one contact structure is need. Circuit wiring of the vertical channel memory device can be also simplified.

In some embodiments, since the gate of the SSL switch, the GSL switch and the IG switches are respectively formed by similar deposition process that is use to form the other memory cells of the vertical channel NAND memory device, thus the gates thickness of the SSL switch, the GSL switch, the IG switches and the other memory cells of the vertical channel NAND memory device may be substantially the same, and the etching deviation of a subsequent etching back process (e.g. for forming floating gates) can be minimized. Such that, the down-stream process for forming the vertical channel NAND memory device can be performed on a robust basis, and the process window and yields thereof can be improved.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A three dimensional (3D) memory device comprising:
a multi-layer stack, comprising a plurality of conductive layers, a first opening and a second opening, wherein the plurality of conductive layers are vertically stacked from and insulated with each other, the first opening and the second opening respectively penetrate through at least two of the plurality of conductive layers;
a first contact layer, disposed in the first opening and electrically connecting the at least two of the plurality of conductive layers penetrated by the first opening, wherein a portion of the first contact layer extends outwards beyond the first opening and has a thickness equal to an average thickness of the plurality of conductive layers;
a memory layer, disposed in the second opening; and
a channel layer, covering on the memory layer, wherein a plurality of memory cells are formed at cross points of the channel layer, the memory layer and the at least two of the plurality of conductive layers penetrated by the second opening.

2. The 3D memory device according to claim 1, wherein the at least two of the plurality of conductive layers electrically connected by the first contact layer serve as a string selection (SSL) switch.

3. The 3D memory device according to claim 1, wherein the at least two of the plurality of conductive layers electrically connected by the first contact layer serve as a ground selection (GSL) switch.

4. The 3D memory device according to claim 2, further comprising:
a third opening penetrating through at least two of the plurality of conductive layers; and
a second contact layer, disposed in the third opening and electrically connecting the at least two of the plurality of conductive layers penetrated by the third opening, wherein the at least two of the plurality of conductive layers penetrated by the third opening are assembled to serve as an inversion assist gate (IG) switch.

5. The 3D memory device according to claim 2, further comprising:
a third opening penetrating through at least two of the plurality of conductive layers; and
a second contact layer, disposed in the third opening and electrically connecting the at least two of the plurality of conductive layers penetrated by the third opening, wherein the at least two of the plurality of conductive layers penetrated by the third opening are assembled to serve as a GSL switch.

6-7. (canceled)

8. The 3D memory device according to claim 1, further comprising a plurality of recesses extending into the multi-layer stack from the second opening, wherein at least a portion of the memory layer extends into the recesses.

9. A method for fabricating a 3D memory device comprising:
providing a multi-layer stack, including a plurality of conductive layers, a first opening and a second opening is provided, wherein the conductive layers are vertical stacked and insulated with each other; the first opening and the second opening respectively penetrate through at least two ones of the conductive layers;
forming a first contact layer in the first opening and electrically connecting the conductive layers penetrated by the first opening;
forming a memory layer in the second opening;
forming a channel on the memory layer, whereby a plurality of memory cells are formed at cross points of the channel layer, the memory layer and the conductive layers penetrated by the second opening.

10. The method according to claim 9, wherein the at least two ones of the conductive layer penetrated by the first opening are assembled to serve as a SL switch.

11. The method according to claim 9, wherein the at least two ones of the conductive layer penetrated by the first opening are assembled to serve as a GSL switch.

12. The method according to claim 9, further comprising:
forming a third opening penetrating through at least two ones of the conductive layers; and
forming a second contact layer, disposed in the third opening and electrically connecting the at least two ones of the conductive layers penetrated by the third opening, wherein the at least two ones of the conductive layers penetrated by the third opening are assembled to serve as an IG switch.

13. The method according to claim 9, further comprising:
forming a third opening penetrating through at least two ones of the conductive layers; and
forming a second contact layer, disposed in the third opening and electrically connecting the at least two ones of the conductive layers penetrated by the third opening, wherein the at least two ones of the conductive layers penetrated by the third opening are assembled to serve as a GSL switch.

14. The method according to claim 9, wherein the conductive layers have an identical thickness (T), the first opening has a width (W) less than or equal to twofold of the product of the identical thickness and a predetermined conformal ratio (r) (W≤2×r×T).

15. The method according to claim 9, wherein the conductive layers have an identical thickness (T), the first opening has a width (W) greater than twofold of the product of the identical thickness and a predetermined conformal ratio (r) (W>2×r×T).

16. The method according to claim 9, prior to forming of the memory layer further comprising performing an etching back process to remove the portions of the conductive layers, so as to define a plurality of recess between each two ones of the insulating layers.
